(19) United States
(12) Patent Application Publication
(10) Pub. No.: US 2019/0378725 A1
(43) Pub. Date: Dec. 12, 2019

(54) METHOD FOR TRANSFERRING A PATTERN FROM AN ORGANIC MASK

(71) Applicant: Lam Research Corporation, Fremont, CA (US)

(72) Inventors: Mirzafer ABATCHEV, Fremont, CA (US); HanJoo CHOE, Mountain View, CA (US); Tom A. KAMP, San Jose, CA (US); Qian FU, Pleasanton, CA (US); In Deog BAE, San Ramon, CA (US); Martin SHIM, Pleasanton, CA (US); Yoko YAMAGUCHI, Union City, CA (US); Jose Ivan PADOVANI BLANCO, Palo Alto, CA (US)

(21) Appl. No.: 16/003,786

(22) Filed: Jun. 8, 2018

(51) Int. Cl. H01L 21/3213; H01L 21/311; H01L 21/02; H01L 21/28

(52) U.S. Cl. CPC H01L 21/32139; H01L 21/31144; H01L 21/28194; H01L 21/0228; H01L 21/32136

(57) ABSTRACT

A method for patterning a stack having a patterned organic mask with a plurality of mask features including sidewalls and tops, a hardmask and an etch layer, wherein the patterned organic mask is positioned over the hardmask which is positioned over the etch layer is provided. An atomic layer deposition is deposited, wherein the depositing the atomic layer deposition controllably trims the plurality of mask features of the patterned organic mask. The atomic layer deposition is broken through. The hardmask is selectively etched with respect to the patterned organic mask, wherein the atomic layer deposition reduces faceting of the plurality of mask features of the patterned organic mask during the selective etching.

### BACKGROUND

The present disclosure relates to the formation of semiconductor devices. More specifically, the disclosure relates to the formation of semiconductor devices requiring etching features.

During semiconductor wafer processing, an intermediate layer below a patterned organic mask may be etched. A pattern may be transferred from an organic mask to a hardmask and then to an etch layer.

### SUMMARY

To achieve the foregoing and in accordance with the purpose of the present disclosure, a method for patterning a stack having a patterned organic mask with a plurality of mask features including sidewalls and tops, a hardmask and an etch layer, wherein the patterned organic mask is positioned over the hardmask which is positioned over the etch layer is provided. An atomic layer deposition is deposited, wherein the depositing the atomic layer deposition controllably trims the plurality of mask features of the patterned organic mask. The atomic layer deposition is broken through. The hardmask is selectively etched with respect to the patterned organic mask, wherein the atomic layer deposition reduces faceting of the plurality of mask features of the patterned organic mask during the selective etching.

These and other features will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of a process that may be used in an embodiment.

FIG. 2 is a schematic view of a plasma processing chamber that may be used in practicing an embodiment.

FIG. 3 illustrates a computer system, which is suitable for implementing a controller used in embodiments.

FIGS. 4A-E are schematic cross-sectional views of a stack processed according to an embodiment.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Low temperature ALD (atomic layer deposition) of silicon oxide (SiO₂) over patterned organic materials, photoresist or spin on carbon (SOC), is widely used for spacer material deposition in edge defined multi-patterning technique. Oxygen (O₂) plasma is one method used for oxidation of silicon (Si) containing precursors. Depending on the parameters O₂ plasma may consume organic material and change critical dimensions (CDs) of the original pattern. Consumption can be considerable and even the remaining core of the organic material can be modified. Final CDs of features, such as line/space or pillars, after SiO₂ deposition can be considerably smaller compared with incoming CDs for thin SiO₂ deposition or can be considerably larger for thick SiO₂ deposition. The method described herein allows better and improved control of CDs by replacing some of the original organic material with SiO₂, which has a better etch resistance compared to the organic material. The method also allows improved line width roughness (LWR) and local/global CD uniformity, because all these parameters reduce linearly with CDs of the original organic core material.

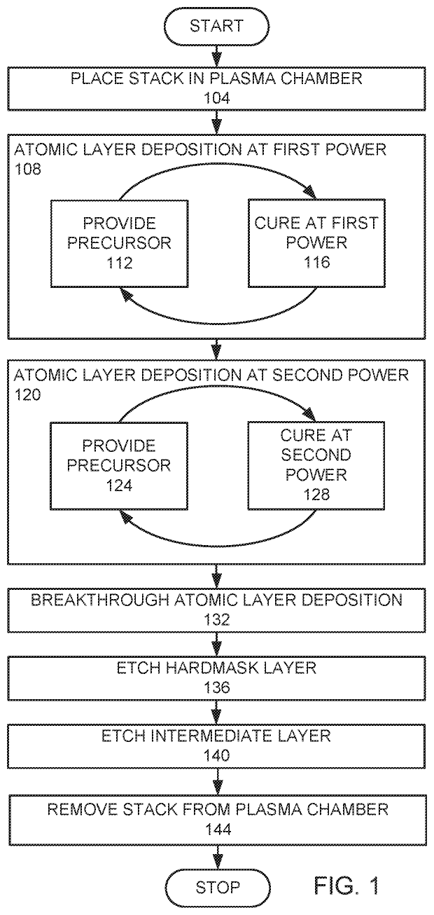

To facilitate understanding, FIG. 1 is a high level flow chart of an embodiment. A stack with a patterned organic mask with mask features including sidewalls and tops over a hardmask over an etch layer is placed on a substrate support in a plasma chamber (step 104). An atomic layer deposition at a first power is provided (step 108). The atomic layer deposition at the first power comprises at least one cycle of providing a precursor (step 112) and curing the precursor at a first power (step 116). An atomic layer deposition at a second power is provided (step 120). The atomic layer deposition at the second power comprises at least one cycle of providing a precursor (step 124) and curing the precursor at the second power. The second power is greater than the first power (step 128). A breakthrough is provided to expose parts of the patterned organic mask or parts of the hardmask layer 412 (step 132). The hardmask layer is selectively etched with respect to the patterned organic mask (step 136). An intermediate layer is selectively etched with respect to the hardmask layer (step 140). The stack is removed from the substrate support in the plasma chamber (step 144).

### Example

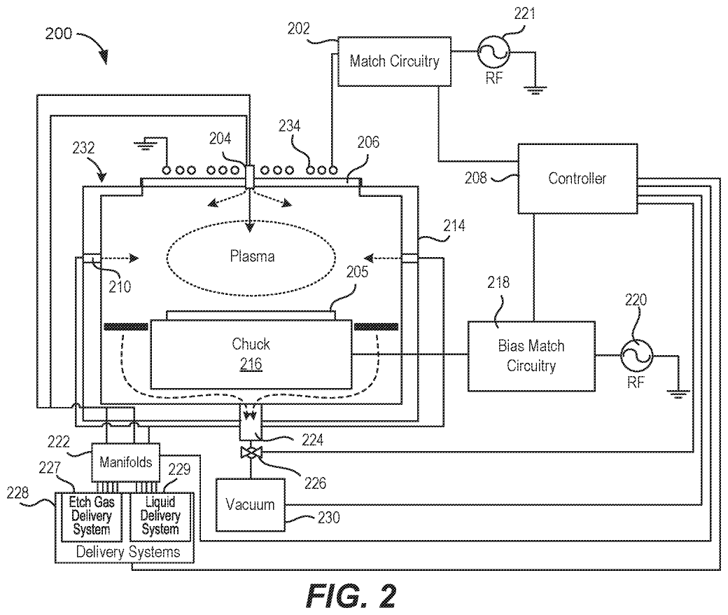

FIG. 2 schematically illustrates an example of a plasma processing system 200 which may be used to perform the process of an embodiment. The system includes a plasma chamber 232 that includes a chamber body 214, a chuck 216, and a dielectric window 206. The plasma chamber 232 includes a processing region and the dielectric window 206 is disposed over the processing region. The chuck 216 can be an electrostatic chuck for supporting a substrate 205 and is disposed in the chamber below the processing region. A transformer coupled plasma (TCP) coil 234 is disposed over the dielectric window 206 and is connected to match circuitry 202, which is connected to a plasma RF (radio frequency) generator 221.

The system includes a bias RF generator 220, which can be defined from one or more generators. If multiple generators are provided, different frequencies can be used to achieve various tuning characteristics. A bias match 218 is coupled between the bias RF generators 220 and a conductive plate of the assembly that defines the chuck 216. The chuck 216 also includes electrostatic electrodes to enable the chucking and dechucking of the wafer. Broadly, a filter and a direct current (DC) clamp power supply can be provided. Other control systems for lifting the wafer off of the chuck 216 can also be provided.

A first gas injector 204 provides two different channels to inject two separate streams of process gases or liquid precursor (in vapor form) to the chamber from the top of the chamber. It should be appreciated that multiple gas supplies may be provided for supplying different gases to the chamber for various types of operations, such as process operations on wafers, waferless auto-cleaning (WAC) operations, and other operations. A second gas injector 210 provides another gas stream that enters the chamber through the side instead of from the top.

Delivery systems 228 includes, in one embodiment, an etch gas delivery system 227 and a liquid delivery system 229. Manifolds 222 are used for selecting, switching, and/or mixing outputs from the respective delivery systems. As will be described in more detail below, the etch gas delivery system is configured to output etchant gases that are optimized to etch one or more layers of materials of a substrate. The manifolds 222 are further optimized, in response to control from the controller 208, to perform atomic layer deposition (ALD). A vacuum pump 230 is connected to the plasma chamber 232 to enable vacuum pressure control and removal of gaseous byproducts from the chamber during operational plasma processing. A valve 226 is disposed between exhaust 224 and the vacuum pump 230 to control the amount of vacuum suction being applied to the chamber.

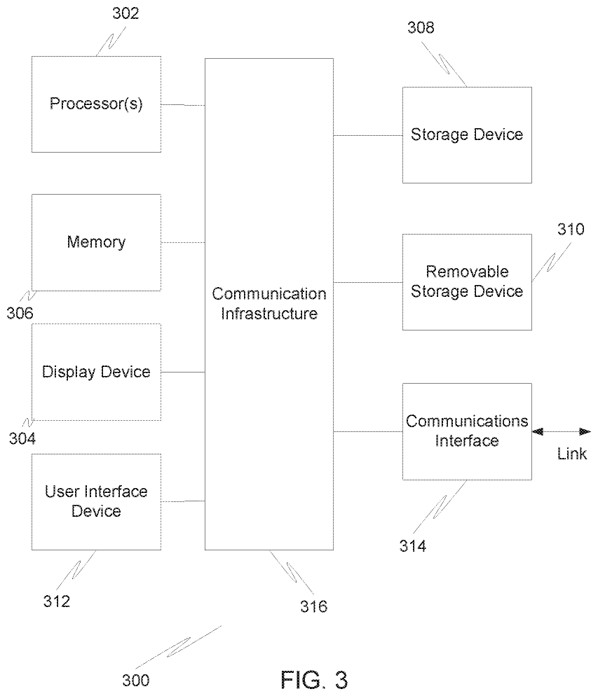

FIG. 3 is a high level block diagram showing a computer system 300, which is suitable for implementing the controller 208 used in an embodiment. The computer system may have many physical forms ranging from an integrated circuit, a printed circuit board, and a small handheld device up to a huge super computer. The computer system 300 includes one or more processors 302, and further can include an electronic display device 304 (for displaying graphics, text, and other data), a main memory 306 (e.g., random access memory (RAM)), storage device 308 (e.g., hard disk drive), removable storage device 310 (e.g., optical disk drive), user interface devices 312 (e.g., keyboards, touch screens, keypads, mice or other pointing devices, etc.), and a communication interface 314 (e.g., wireless network interface). The communication interface 314 allows software and data to be transferred between the computer system 300 and external devices via a link. The system may also include a communications infrastructure 316 (e.g., a communications bus, cross-over bar, or network) to which the aforementioned devices/modules are connected.

Information transferred via communications interface 314 may be in the form of signals such as electronic, electromagnetic, optical, or other signals capable of being received by communications interface 314, via a communication link that carries signals and may be implemented using wire or cable, fiber optics, a phone line, a cellular phone link, a radio frequency link, and/or other communication channels. With such a communications interface, it is contemplated that the one or more processors 302 might receive information from a network, or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

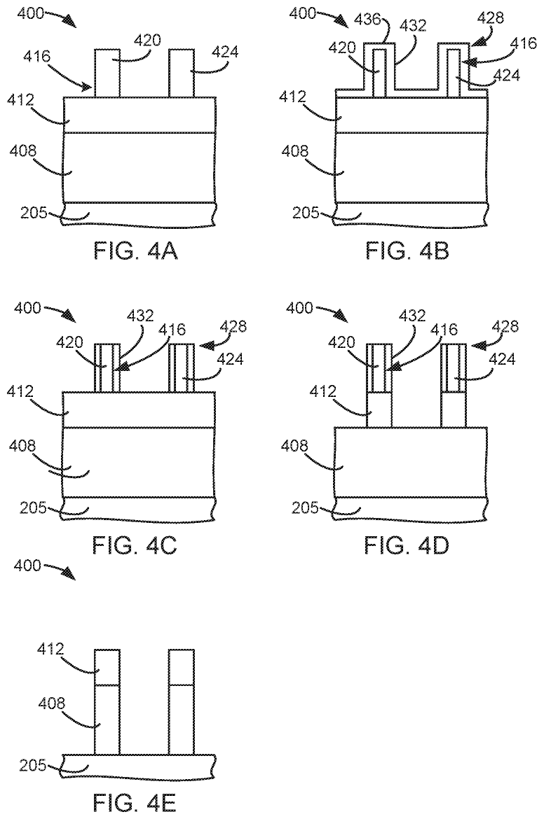

In an example of an implementation of the embodiment, a stack is placed on a substrate support in a plasma chamber (step 104). FIG. 4A is a cross sectional view of a stack 400 with a substrate 205. The substrate 205 is disposed below an intermediate layer 408. The intermediate layer 408 is disposed below a hardmask layer 412. The hardmask 412 is disposed below a patterned organic mask 416. In this example, the patterned organic mask 416 is a patterned organic mask, such as a photoresist mask, with a first mask feature 420 and a second mask feature 424. In this example, the hardmask layer 412 is polysilicon. One or more layers (not shown) may be disposed between the substrate 205 and the intermediate layer 408. One or more layers (not shown) may also be disposed between the intermediate layer 408 and the hardmask layer 412. One or more layers (not shown), such as an antireflective coating, may also be disposed between the hardmask layer 412 and the patterned organic mask 416.

An atomic layer deposition at a first power is provided (step 108) to achieve a deposit at a first thickness. The atomic layer deposition at the first power (step 108) comprises at least one cycle of providing a precursor (step 112) and curing the precursor at the first power (step 116). The precursor is provided to the mask features (step 112). In this embodiment, a liquid silicon containing precursor is vaporized and delivered in vapor form into the plasma chamber 232, to dose the mask features 420, 424 to saturation, forming a layer of precursor over the mask features 420, 424. Once the mask features 420, 424 are dosed with the precursor, the delivery of the precursor vapor is stopped by the manifolds 222. The precursor is then cured (step 116), which in an embodiment is accomplished by subjecting the stack 400 to a flash process. The flash process includes powering the plasma chamber 232 using the RF generator 221 to provide the first power and delivering 1000 sccm to 2000 sccm oxygen (O₂) to the plasma chamber 232. In this example, the first power is 500 watts delivered at 13.56 MHz. A pressure of 20 mTorr to 100 mTorr is provided. This flash process is referred to as an “O₂ flash” operation, as the time during which the first power is delivered is relatively fast, e.g., between about 0.5 second and about 4 seconds. The O₂ flash operation forms a silicon oxide monolayer on the mask features 420 and 424 using the monolayer of the silicon containing precursor. Once the O₂ flash operation is completed, the plasma chamber 232 is purged. The cycle may then be repeated.

In an embodiment of the ALD cycle, any suitable liquid precursor capable of forming a conformal atomic layer can be used. By way of non-limiting example, the liquid precursor can have a composition of the general type C(x)H(y)N(z)O(a)Si(b). In some embodiments, the liquid precursor has one of the following compositions: C₆H₁₉N₃Si, C₈H₂₂N₂Si, C₉H₂₃NO₃Si, and C₁₂H₂₈O₄Si. In this example, the providing of the precursor is plasmaless. The precursor has a silicon function group, which forms a monolayer on the mask features 420 and 424, since the precursor does not attach to another precursor.

An atomic layer deposition at a second power is then provided (step 120) to achieve a second thickness. The atomic layer deposition at the second power (step 120) comprises at least one cycle of providing a precursor (step 124) and curing the precursor at the second power (step 128). The precursor is provided to the mask features 420 and 424 (step 124). In this embodiment, a liquid silicon containing precursor is vaporized and delivered in vapor form into the plasma chamber 232, to dose the mask features 420, 424 to saturation, forming a layer of precursor over the mask features 420, 424. Once the mask features 420, 424 are dosed with the precursor, the delivery of the vapor is stopped by the manifolds 222. The precursor is then cured (step 128), which in an embodiment is accomplished by subjecting the stack 400 to another flash process. This other flash process similarly includes powering the plasma chamber 232 using the RF generator 221 to provide the second power and delivering 1000 sccm to 2000 sccm oxygen (O₂) to the plasma chamber 232. In this example, the second power is 2500 watts delivered at 13.56 MHz. A pressure of 20 mTorr to 100 Torr is provided. This other flash process is also an O₂ flash operation. Similarly, the O₂ flash operation forms a silicon oxide monolayer on the mask features 420 and 424 using the monolayer of the silicon containing precursor. Once the O₂ flash operation is completed, the plasma chamber 232 is purged. The cycle may then be repeated.

FIG. 4B is a cross sectional view of the stack 400 after the atomic layer deposition at the first power (step 108) and the atomic layer deposition at the second power (step 120). An ALD layer 428 is formed over the patterned organic mask 416 including the mask features 420 and 424. The ALD layer 428 has sidewalls 432 formed over sidewalls of the mask features 420, 424 and top portions 436 formed over the respective tops of the mask features 420, 424. In this example, the mask features 420, 424 are trimmed by the atomic layer deposition at the first power (step 108) and the atomic layer deposition at the second power (step 120). The first power and the second power and the number of cycles at the first power and the second power may be used as tuning parameters to control the trimming of the mask features 420, 424.

A breakthrough process is provided (step 132), which directionally etches the top/horizontal portions 436 of the ALD layer 428 with respect to the sidewalls 432 of the ALD layer 428. In this embodiment, since the top portions 436 of the ALD layer 428 are horizontal and the sidewalls 432 are vertical, the breakthrough process (step 132) directionally etches horizontal layers with respect to vertical layers. An example of an etch for providing a directional etch would be a fluorine based highly ion assisted etch. An example of a breakthrough process provides a pressure of 3 mTorr. A breakthrough gas of 7 sccm O₂, 40 sccm trifluormethane (CHF₃), 80 sccm carbon tetrafluoride (CF₄), and 50 sccm helium (He) is flowed into the plasma chamber 232. The TCP coil 234 provides 550 watts of RF power at 13.56 MHz, which transforms the breakthrough gas into a plasma. 50 volts of bias is provided. After the breakthrough process is completed, the flow of the breakthrough gas into the plasma chamber 232 is stopped.

FIG. 4C is a cross sectional view of the stack 400 after the breakthrough process (step 132) is complete. The horizontal portions of the ALD layer 428 have been etched away. The sidewalls 432 of the ALD layer 428 remain. The respective tops of the first mask feature 420 and the second mask feature 424 are exposed. In this example, portions of the ALD layer 428 previously covering horizontal surfaces over the hardmask layer 412 are also etched away. In this example, the sidewalls 432 of the ALD layer 428 are trimmed. The resulting first mask feature 420 and second mask feature 424 and the sidewalls 432 of the ALD layer 428, collectively form features which are the same width as the first mask feature 420 and second mask feature 424 before the first mask feature 420 and second mask feature 424 were trimmed by the atomic layer deposition at the first power (step 108) and the atomic layer deposition at the second power (step 120).

The hardmask layer 412 is then selectively etched with respect to the patterned organic mask 416 (step 136). An example recipe for selectively etching the hardmask layer 412 with respect to the patterned organic mask 416 provides a hardmask etch gas of 500 sccm hydrogen bromide (HBr) and 50 sccm He, which is flowed into the plasma chamber 232. A pressure of 80 mTorr is provided. The TCP coil 234 provides 900 watts of RF power at 13.56 MHz, which transforms the hardmask etch gas into a plasma. 500 volts of bias is provided. After the hardmask etch process is completed, the flow of the hardmask etch gas into the plasma chamber 232 is stopped.

FIG. 4D is a cross sectional view of the stack 400 after the hardmask layer 412 is selectively etched (step 136). Without the sidewalls 432 of the ALD layer 428, the sidewalls of the first mask feature 420 and second mask feature 424 would facet, causing tapering of the features formed in the hardmask layer 412. The faceting would also increase line edge roughness and line width roughness and would reduce CD uniformity.

The intermediate layer 408 is then selectively etched with respect to the hardmask layer 412 (step 140). In this example, the intermediate layer 408 is silicon oxide (SiO₂). An example of a recipe flows an intermediate layer etch gas of 10 sccm CF₄, 4 sccm hexafluoro-2-butyne (C₄F₆), and 500 sccm argon (Ar) into the plasma chamber 232. A pressure of 10 mTorr is provided. The TCP coil 234 provides 900 watts of RF power at 13.56 MHz, which transforms the intermediate layer etch gas into a plasma. 1000 volts of pulsed bias with a frequency of 200 Hz at a 20% duty cycle is provided. After the intermediate layer 408 etch process is completed, the flow of the intermediate layer etch gas into the plasma chamber 232 is stopped. The patterned organic mask 416 and the sidewalls 432 of the ALD layer 428 may be etched away during this step or a separate step may be used to remove the patterned organic mask 416 and the sidewalls of the ALD layer 428. FIG. 4E is a cross sectional view of the stack 400 after the intermediate layer 408 is selectively etched with respect to the hardmask layer 412.

Additional processes may be provided. For example, the hardmask layer 412 may be removed. The stack 400 is removed from the plasma chamber (step 144).

The ALD layer 428 reduces faceting of the patterned organic mask 416. As a result, the pattern is transferred from the patterned organic mask 416 to the hardmask layer 412 with less tapering and degradation of the pattern. The ALD layer 428 also reduces line edge roughness and line width roughness and would increase CD uniformity. The ALD layer 428 may also remove defects in the patterned organic mask 416. Depositing an ALD layer over the patterned organic mask 416 and then providing a breakthrough can decrease the width of the resulting mask features, because the oxide plasma curing of the ALD process may cause trimming of the patterned organic mask 416. In addition, the breakthrough may further trim the resulting mask features. Furthermore, the depositing an ALD layer over the patterned organic mask 416 and then providing a breakthrough may increase the width of the resulting mask features, since the depositing an ALD layer may increase the width of the resulting mask features by the added thickness of the ALD layer, if little of the patterned organic mask 416 is trimmed. Various embodiments use the first power, the second power, and the number of cycles at each power and parameters of the breakthrough as tuning parameters for the ultimate net gain or loss of the width of the mask features, while providing a protective layer that reduces patterned organic mask 416 faceting. In this embodiment, the width of the final mask features after breakthrough is about equal to the original width of the features of the patterned organic mask 416. Other embodiments may provide final mask features with widths that are narrower or wider than the original width of the features of the patterned organic mask 416. In addition, the first power, the second power and the number of cycles at each power and parameters of the breakthrough are used as tuning parameters to reduce line width roughness, line edge roughness, and/or organic mask defects and/or to increase CD uniformity. In some embodiments, the increase in CD uniformity is a result of the combination of the trimming of the organic pattern mask 416 and the added thicknesses on sidewalls of the features of the ALD layer 428. The widths of the resulting features would be the sum of the width of the trimmed organic pattern mask 416 features and the thicknesses of the ALD layer 428 on sidewalls of the trimmed organic patterned mask 416.

In the above example, the precursor was a silicon containing polymer to bind to the patterned organic mask 416, to form a self-limiting silicon containing monolayer. In this example, the silicon containing polymer is a polymer with a silicon functional group. In various embodiments, the precursor may be a liquid, a vapor of a liquid, or a gas. Such precursors are generally described as being in fluid form. The curing of the precursor forms the silicon containing monolayer into a silicon oxide monolayer. Subsequent layers would use the precursor to form a self-limiting silicon containing monolayer over the silicon oxide containing sidewall, which is cured to add an additional monolayer of silicon oxide. In this example, the precursor is able to form a monolayer on different types of material, such as a silicon containing material or an organic material.

In various embodiments, the curing of the monolayer may be done by applying RF power to the plasma chamber along with an oxygen gas to perform a plasma flash process (or O₂ plasma cure), the plasma flash process being performed for a period of time that is between about 0.2 second and about 4 seconds, and the RF power is applied at a power level that is between about 200 watts and about 3,000 watts. The O₂ plasma cure converts the Si containing precursor into SiO₂.

In various embodiments, different recipes may be used to break through the tops of ALD layer with respect to sidewalls of the ALD layer. Spacer etch recipes may be used to accomplish this in different embodiments. In some embodiments, during the ALD process, a purge phase may be provided after the precursor is provided and before the curing and/or after the curing and before providing the precursor. In various embodiments, the hardmask may be of different materials, such as polysilicon or silicon oxynitride. In various embodiments, the breakthrough does not expose the tops of the mask features 420, 424, but instead exposes parts of a tip surface of the hardmask layer 412.

The above embodiments are performed in situ in a single chamber, without moving the chuck or removing the stack from the chuck. Such embodiments provide faster and less expensive throughput. In addition, thinner layers may be applied, since the in situ process allows for a greater number of cycles, which allows for the improved feature shapes.

In the above embodiment, the second power is greater than the first power. In some embodiments, the second power is greater than twice the first power. The higher level of the second power results in a better quality of the deposited film and improves etch resistance of the film. The limiting factor of higher power is possibility of additional uncontrollable trimming of CDs, which depends on the number of cycles and power level in first deposition at first power level.

While this disclosure has been described in terms of several preferred embodiments, there are alterations, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

1. A method for patterning a stack having a patterned organic mask with a plurality of mask features including sidewalls and tops, a hardmask and an etch layer, wherein the patterned organic mask is positioned over the hardmask which is positioned over the etch layer, comprising:
depositing an atomic layer deposition, wherein the depositing the atomic layer deposition trims the plurality of mask features of the patterned organic mask, wherein the depositing the atomic layer deposition comprises:
a first plurality of cycles for depositing a first thickness of the atomic layer deposition, wherein each of the first plurality of cycles comprises:
flowing a first precursor to deposit a first layer of precursor over the patterned organic mask; and
curing the first layer of precursor over the patterned organic mask to form a first layer as part of the atomic layer deposition, wherein the curing the first layer of precursor comprises: providing a first radio frequency (RF) power along with an oxygen gas to perform a plasma flash process for a first period of time; and
a second plurality of cycles for depositing a second thickness of the atomic layer deposition, wherein each of the second plurality of cycles comprises:
flowing a second precursor to deposit a second layer of precursor over the patterned organic mask; and
curing the second layer of precursor over the patterned organic mask to form a second layer as part of the atomic layer deposition, wherein the curing the second layer of precursor comprises providing a second RF power along with the oxygen gas to perform the plasma flash process for a second period of time, wherein either the second RF power is greater than the first RF power or the second period of time is greater than the first period of time or both;
breaking through the atomic layer deposition; and
selectively etching the hardmask with respect to the patterned organic mask, wherein the atomic layer deposition reduces faceting of the plurality of mask features of the patterned organic mask during the selective etching.

2. The method, as recited in claim 1, wherein the depositing the atomic layer deposition trims the plurality of mask features of the patterned organic mask to reduce at least one of line width roughness, line edge roughness, and organic mask defects.

3. The method, as recited in claim 1, wherein the depositing the atomic layer deposition trims the plurality of mask features of the patterned organic mask to reduce at least a width of one of the plurality of mask features of the patterned organic mask.

4. The method, as recited in claim 1, wherein the depositing the atomic layer deposition trims the plurality of mask features of the patterned organic mask to increase CD uniformity.

5. (canceled)

6. The method, as recited in claim 5, wherein the first and second precursors are silicon containing polymers.

7. The method, as recited in claim 5, wherein the first and second precursors are polymers with a silicon functional group.

8. The method, as recited in claim 5, wherein at least one of the flowing the first precursor and the flowing of the second precursor is plasmaless.

9. (canceled)

10. The method, as recited in claim 1, wherein the patterned organic mask is made of a carbon containing material.

11. The method, as recited in claim 1, wherein the atomic layer deposition is made of a silicon oxide containing material.

12. The method, as recited in claim 1, wherein the breaking through the atomic layer deposition exposes the tops of the plurality of mask features.

13. The method, as recited in claim 12, wherein after the breaking through the atomic layer deposition atomic layer deposition remains on sidewalls of the plurality of mask features.

14. The method, as recited in claim 1, further comprising selectively etching the etch layer with respect to the hardmask.

15. The method, as recited in claim 1, wherein the hardmask comprises at least one of silicon oxynitride or polysilicon.

16. The method, as recited in claim 1, wherein the atomic layer deposition increases at least a width of one of the plurality of mask features.

17. The method, as recited in claim 1, wherein the depositing the atomic layer deposition trims the patterned organic mask reducing a width of the patterned organic mask and wherein the deposition of the atomic layer increases a width defined by a sum of the width of the patterned organic mask and the thicknesses of the atomic layer deposition wherein the CD uniformity is a result of the trimming of the plurality of mask features of the patterned organic mask and the deposition of the atomic layer deposition

18. The method, as recited in claim 1, wherein the depositing an atomic layer deposition, the breaking through, and the selective etching are performed in situ in a same chamber.
